(19) United States
(12) Patent Application Publication
(10) Pub. No.: US 2007/0175393 A1
(43) Pub. Date: Aug. 2, 2007

(54) SUBSTRATE PROCESSING APPARATUS, SUBSTRATE PROCESSING METHOD, AND STORAGE MEDIUM STORING PROGRAM FOR IMPLEMENTING THE METHOD

(75) Inventors: Eiichi NISHIMURA, Nirasaki-shi (JP); Takamichi Kikuchi, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/668,684

(22) Filed: Jan. 30, 2007

(30) Foreign Application Priority Data
Jan. 31, 2006 (JP) 2006-023098

(51) Int. Cl. C23C 16/00; H01L 21/306

(52) U.S. Cl. 118/715; 156/345.33

(57) ABSTRACT

A substrate processing apparatus that enables an oxide layer and an organic layer to be removed efficiently. A substrate formed at its surface with an organic layer covered with the oxide layer is housed in a chemical reaction processing apparatus of the substrate processing apparatus, in which the oxide layer is subjected to chemical reaction with gas molecules, and thus a product is produced on the substrate surface. The substrate is heated in a chamber of a heat treatment apparatus of the substrate processing apparatus, whereby the product is vaporized and the organic layer is exposed. Microwaves are then introduced into the chamber into which oxygen gas is supplied, whereby there are produced oxygen radicals that decompose and remove the organic layer.

### BACKGROUND OF THE INVENTION

1. Field of the Invention

The present invention relates to a substrate processing apparatus, a substrate processing method, and a storage medium storing a program for implementing the method, and in particular relates to a substrate processing apparatus and a substrate processing method for removing an organic layer.

2. Description of the Related Art

In a method of manufacturing electronic devices in which electronic devices are manufactured from a silicon wafer (hereinafter referred to merely as a “wafer”), a film formation step of forming a conductive film or an insulating film on a surface of the wafer using CVD (chemical vapor deposition) or the like, a lithography step of forming a photoresist layer in a desired pattern on the formed conductive film or insulating film, and an etching step of fabricating the conductive film into gate electrodes, or fabricating wiring grooves or contact holes in the insulating film, with plasma produced from a processing gas using the photoresist layer as a mask are repeatedly implemented in this order.

For example, in one electronic device manufacturing method, floating gates comprised of an SiN (silicon nitride) layer and a polysilicon layer formed on a wafer are etched using an HBr (hydrogen bromide)-based processing gas, an inter-layer SiO₂ film below the floating gates is etched using a CHF₃-based processing gas, and then an Si layer below the inter-layer SiO₂ film is etched using an HBr (hydrogen bromide)-based processing gas. In this case, a deposit film 181 comprised of three layers is formed on side surfaces of trenches 180 formed in the wafer (see FIG. 13). The deposit film is comprised of an SiOBr layer 182, a CF-type deposit layer 183, and an SiOBr layer 184 corresponding to the respective processing gases. The SiOBr layers 182 and 184 are pseudo-SiO₂ layers having properties similar to those of an SiO₂ layer, and the CF-type deposit layer 183 is an organic layer.

The SiOBr layers 182 and 184 and the CF-type deposit layer 183 cause problems for the electronic devices such as continuity defects, and hence must be removed.

As a pseudo-SiO₂ layer removal method, there is known a substrate processing method in which the wafer is subjected to COR (chemical oxide removal) and PHT (post heat treatment). The COR is processing in which the pseudo-SiO₂ layer is made to undergo chemical reaction with gas molecules to produce a product, and the PHT is processing in which the wafer that has been subjected to the COR is heated so as to vaporize and thermally oxidize the product that has been produced on the wafer through the chemical reaction in the COR, thus removing the product from the wafer.

As a substrate processing apparatus for implementing such a substrate processing method comprised of COR and PHT, there is known a substrate processing apparatus having a chemical reaction processing apparatus, and a heat treatment apparatus connected to the chemical reaction processing apparatus. The chemical reaction processing apparatus has a chamber, and carries out the COR on a wafer housed in the chamber. The heat treatment apparatus also has a chamber, and carries out the PHT on a wafer housed in the chamber (see, for example, specification of U.S. Laid-open Patent Publication No. 2004/0185670).

However, in the case of removing the SiOBr layer 184, which is a pseudo-SiO₂ layer, using the above substrate processing apparatus, the CF-type deposit layer 183 is exposed. The CF-type deposit layer 183 is not vaporized even upon carrying out the heat treatment, and moreover does not undergo chemical reaction with the gas molecules to produce a product, and hence it is difficult to remove the CF-type deposit layer 183 using the above substrate processing apparatus. It is thus difficult to efficiently remove the SiOBr layer 184 and the CF-type deposit layer 183.

### SUMMARY OF THE INVENTION

It is an object of the present invention to provide a substrate processing apparatus, a substrate processing method, and a storage medium storing a program for implementing the method, that enable an oxide layer and an organic layer to be removed efficiently.

To attain the above object, in a first aspect of the present invention, there is provided a substrate processing apparatus that carries out processing on a substrate having formed on a surface thereof an organic layer covered with an oxide layer, the substrate processing apparatus comprising a chemical reaction processing apparatus that subjects the oxide layer to chemical reaction with gas molecules so as to produce a product on the surface of the substrate, and a heat treatment apparatus that heats the substrate on the surface of which the product has been produced, wherein the heat treatment apparatus comprises a housing chamber in which the substrate is housed, an oxygen gas supply system that supplies oxygen gas into the housing chamber, and a microwave introducing apparatus that introduces microwaves into the housing chamber.

According to the substrate processing apparatus of this invention, the heat treatment apparatus has an oxygen gas supply system that supplies oxygen gas into the housing chamber in which the substrate is housed, and a microwave introducing apparatus that introduces microwaves into the housing chamber. For the substrate having formed on a surface thereof an organic layer covered with an oxide layer, upon the product produced from the oxide layer through chemical reaction with the gas molecules being heated, the product is vaporized so as to expose the organic layer. Moreover, upon microwaves being introduced into the housing chamber into which the oxygen gas has been supplied, oxygen radicals are produced. The exposed organic layer is exposed to the produced oxygen radicals, whereupon the oxygen radicals decompose the organic layer. As a result, the organic layer can be removed continuously following on from the oxide layer, and hence the oxide layer and the organic layer can be removed efficiently.

Preferably, the microwave introducing apparatus has a disk-shaped antenna disposed such as to face the substrate housed in the housing chamber, and an electromagnetic wave absorber disposed such as to surround a peripheral portion of the antenna.

According to the substrate processing apparatus of the above preferred embodiment, an electromagnetic wave absorber is disposed such as to surround a peripheral portion of the antenna of the microwave introducing apparatus. As a result, standing waves (transverse waves) in the microwaves from the antenna can be absorbed, and hence emission of such standing waves can be suppressed.

Preferably, the organic layer is a layer made of CF-type deposit.

According to the above substrate processing apparatus of the above preferred embodiment, the organic layer is a layer made of CF-type deposit. Such CF-type deposit can easily be decomposed by the oxygen radicals produced from the oxygen gas upon the application of the microwaves. The organic layer can thus be removed yet more efficiently.

To attain the above object, in a second aspect of the present invention, there is provided a substrate processing method for carrying out processing on a substrate having formed on a surface thereof an organic layer covered with an oxide layer, the substrate processing method comprising a chemical reaction processing step of subjecting the oxide layer to chemical reaction with gas molecules so as to produce a product on the surface of the substrate, a heat treatment step of heating the substrate on the surface of which the product has been produced, an oxygen gas supply step of supplying oxygen gas toward an upper portion of the substrate on which the heat treatment has been carried out, and a microwave introducing step of introducing microwaves toward the upper portion of the substrate onto which the oxygen gas has been supplied.

According to the substrate processing method of this invention, for the substrate having formed on a surface thereof an organic layer covered with an oxide layer, the oxide layer is subjected to chemical reaction with gas molecules so as to produce a product on the surface of the substrate, the substrate on the surface of which the product has been produced is heated, oxygen gas is supplied toward an upper portion of the substrate on which the heat treatment has been carried out, and microwaves are introduced toward the upper portion of the substrate onto which the oxygen gas has been supplied. Upon the product produced from the oxide layer through the chemical reaction with the gas molecules being heated, the product is vaporized so as to expose the organic layer. Moreover, upon the microwaves being introduced toward the upper portion of the substrate onto which the oxygen gas has been supplied, oxygen radicals are produced. The exposed organic layer is exposed to the produced oxygen radicals, whereupon the oxygen radicals decompose the organic layer. As a result, the organic layer can be removed continuously following on from the oxide layer, and hence the oxide layer and the organic layer can be removed efficiently.

To attain the above object, in a third aspect of the present invention, there is provided a storage medium storing a program for causing a computer to implement a substrate processing method for carrying out processing on a substrate having formed on a surface thereof an organic layer covered with an oxide layer, the program comprising a chemical reaction processing module for subjecting the oxide layer to chemical reaction with gas molecules so as to produce a product on the surface of the substrate, a heat treatment module for heating the substrate on the surface of which the product has been produced, an oxygen gas supply module for supplying oxygen gas toward an upper portion of the substrate on which the heat treatment has been carried out, and a microwave introducing module for introducing microwaves toward the upper portion of the substrate onto which the oxygen gas has been supplied.

The above and other objects, features, and advantages of the invention will become more apparent from the following detailed description taken in conjunction with the accompanying drawings.

### BRIEF DESCRIPTION OF THE DRAWINGS

FIG. 1 is a plan view schematically showing the construction of a substrate processing apparatus according to an embodiment of the present invention;

FIGS. 2A and 2B are sectional views of a second processing unit appearing in FIG. 1; specifically:

FIG. 2A is a sectional view taken along line II-II in FIG. 1; and

FIG. 2B is an enlarged view of a portion A shown in FIG. 2A;

FIG. 3 is a sectional view of a third processing unit appearing in FIG. 1;

FIG. 4 is a plan view schematically showing the construction of an oxygen gas supply ring appearing in FIG. 3;

FIG. 5 is a plan view schematically showing the construction of a slot electrode appearing in FIG. 3;

FIGS. 6A, 6B, and 6C are plan views showing variations of the slot electrode shown in FIG. 5; specifically:

FIG. 6A is a view showing a first variation;

FIG. 6B is a view showing a second variation; and

FIG. 6C is a view showing a third variation;

FIG. 7 is a perspective view schematically showing the construction of a second process ship appearing in FIG. 1;

FIG. 8 is a diagram schematically showing the construction of a unit-driving dry air supply system for a second load lock unit appearing in FIG. 7;

FIG. 9 is a diagram schematically showing the construction of a system controller for the substrate processing apparatus shown in FIG. 1;

FIG. 10 is a flowchart of a deposit film removal process as a substrate processing method according to the above embodiment;

FIG. 11 is a plan view schematically showing the construction of a first variation of the substrate processing apparatus according to the above embodiment;

FIG. 12 is a plan view schematically showing the construction of a second variation of the substrate processing apparatus according to the above embodiment; and

FIG. 13 is a sectional view showing a deposit film comprised of an SiOBr layer, a CF-type deposit layer, and an SiOBr layer.

### DETAILED DESCRIPTION OF THE PREFERRED EMBODIMENTS

The present invention will now be described in detail with reference to the drawings showing preferred embodiments thereof.

First, a substrate processing apparatus according to an embodiment of the present invention will be described.

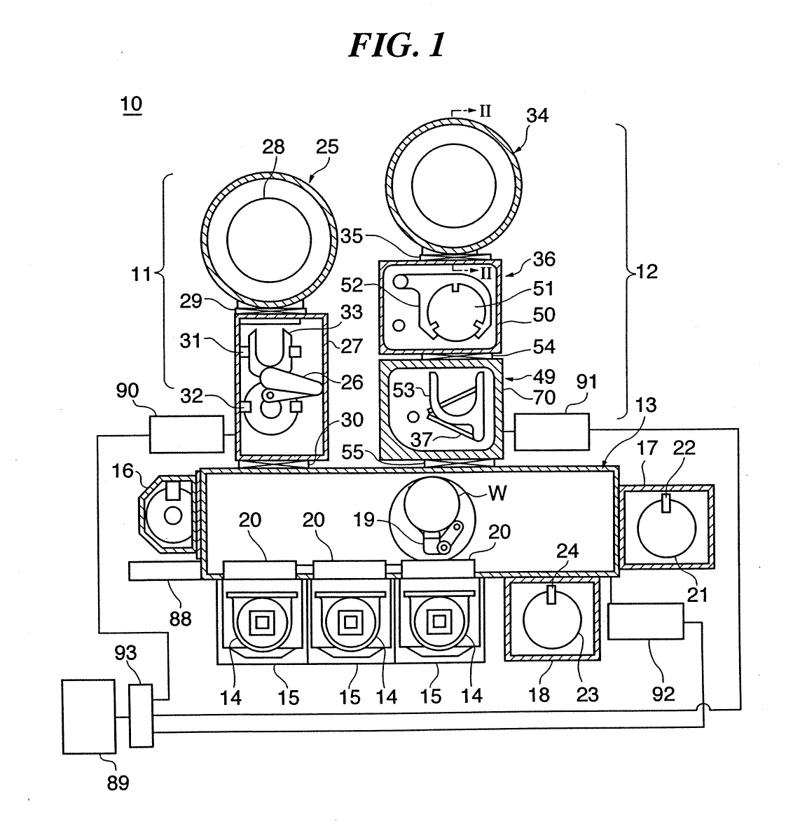

FIG. 1 is a plan view schematically showing the construction of the substrate processing apparatus according to the present embodiment.

As shown in FIG. 1, the substrate processing apparatus 10 has a first process ship 11 for carrying out etching on electronic device wafers (hereinafter referred to merely as “wafers”) (substrates) W, a second process ship 12 that is disposed parallel to the first process ship 11 and is for carrying out COR, PHT, and organic layer removal processing, described below, on the wafers W on which the etching has been carried out in the first process ship 11, and a loader unit 13, which is a rectangular common transfer chamber to which each of the first process ship 11 and the second process ship 12 is connected.

In addition to the first process ship 11 and the second process ship 12, the loader unit 13 has connected thereto three FOUP mounting stages 15 on each of which is mounted a FOUP (front opening unified pod) 14, which is a container housing twenty-five of the wafers W, an orienter 16 that carries out pre-alignment of the position of each wafer W transferred out from a FOUP 14, and first and second IMS's (Integrated Metrology Systems, made by Therma-Wave, Inc.) 17 and 18 for measuring the surface state of each wafer W.

The first process ship 11 and the second process ship 12 are each connected to a side wall of the loader unit 13 in a longitudinal direction of the loader unit 13, disposed facing the three FOUP mounting stages 15 with the loader unit 13 therebetween. The orienter 16 is disposed at one end of the loader unit 13 in the longitudinal direction of the loader unit 13. The first IMS 17 is disposed at the other end of the loader unit 13 in the longitudinal direction of the loader unit 13. The second IMS 18 is disposed alongside the three FOUP mounting stages 15.

A SCARA-type dual arm transfer arm mechanism 19 for transferring the wafers W is disposed inside the loader unit 13, and three loading ports 20 through which the wafers W are introduced into the loader unit 13 are disposed in a side wall of the loader unit 13 in correspondence with the FOUP mounting stages 15. The transfer arm mechanism 19 takes a wafer W out from a FOUP 14 mounted on a FOUP mounting stage 15 through the corresponding loading port 20, and transfers the removed wafer W into and out of the first process ship 11, the second process ship 12, the orienter 16, the first IMS 17, and the second IMS 18.

The first IMS 17 is an optical monitor having a mounting stage 21 on which is mounted a wafer W that has been transferred into the first IMS 17, and an optical sensor 22 that is directed at the wafer W mounted on the mounting stage 21. The first IMS 17 measures the surface shape of the wafer W, for example the thickness of a surface layer, and CD (critical dimension) values of wiring grooves, gate electrodes and so on. Like the first IMS 17, the second IMS 18 is also an optical monitor, and has a mounting stage 23 and an optical sensor 24. The second IMS 18 measures the number of particles on the surface of each wafer W.

The first process ship 11 has a first processing unit 25 in which etching is carried out on each wafer W, and a first load lock unit 27 containing a link-type single pick first transfer arm 26 for transferring each wafer W into and out of the first processing unit 25.

The first processing unit 25 has a cylindrical processing chamber (chamber). An upper electrode and a lower electrode are disposed in-the chamber, the distance between the upper electrode and the lower electrode being set to an appropriate value for carrying out the etching on each wafer W. Moreover, the lower electrode has in a top portion thereof an ESC (electrostatic chuck) 28 for chucking the wafer W thereto using a Coulomb force or the like.

In the first processing unit 25, a processing gas is introduced into the chamber and an electric field is generated between the upper electrode and the lower electrode, whereby the introduced processing gas is turned into plasma so as to produce ions and radicals. The wafer W is etched by the ions and radicals.

In the first process ship 11, the internal pressure of the first processing unit 25 is held at vacuum, whereas the internal pressure of the loader unit 13 is held at atmospheric pressure. The first load lock unit 27 is thus provided with a vacuum gate valve 29 in a connecting part between the first load lock unit 27 and the first processing unit 25, and an atmospheric gate valve 30 in a connecting part between the first load lock unit 27 and the loader unit 13, whereby the first load lock unit 27 is constructed as a preliminary vacuum transfer chamber whose internal pressure can be adjusted.

Within the first load lock unit 27, the first transfer arm 26 is disposed in an approximately central portion of the first load lock unit 27; first buffers 31 are disposed toward the first processing unit 25 with respect to the first transfer arm 26, and second buffers 32 are disposed toward the loader unit 13 with respect to the first transfer arm 26. The first buffers 31 and the second buffers 32 are disposed on a track along which a supporting portion (pick) 33 moves, the supporting portion 33 being disposed at a distal end of the first transfer arm 26 and being for supporting each wafer W. After having being subjected to the etching, each wafer W is temporarily laid by above the track of the supporting portion 33, whereby swapping over of the wafer W that has been subjected to the etching and a wafer W yet to be subjected to the etching can be carried out smoothly in the first processing unit 25.

The second process ship 12 has a second processing unit 34 (chemical reaction processing apparatus) in which COR is carried out on each wafer W, a third processing unit 36 (heat treatment apparatus) that is connected to the second processing unit 34 via a vacuum gate valve 35 and in which PHT and organic layer removal processing are carried out on each wafer W, and a second load lock unit 49 containing a link-type single pick second transfer arm 37 for transferring each wafer W into and out of the second processing unit 34 and the third processing unit 36.

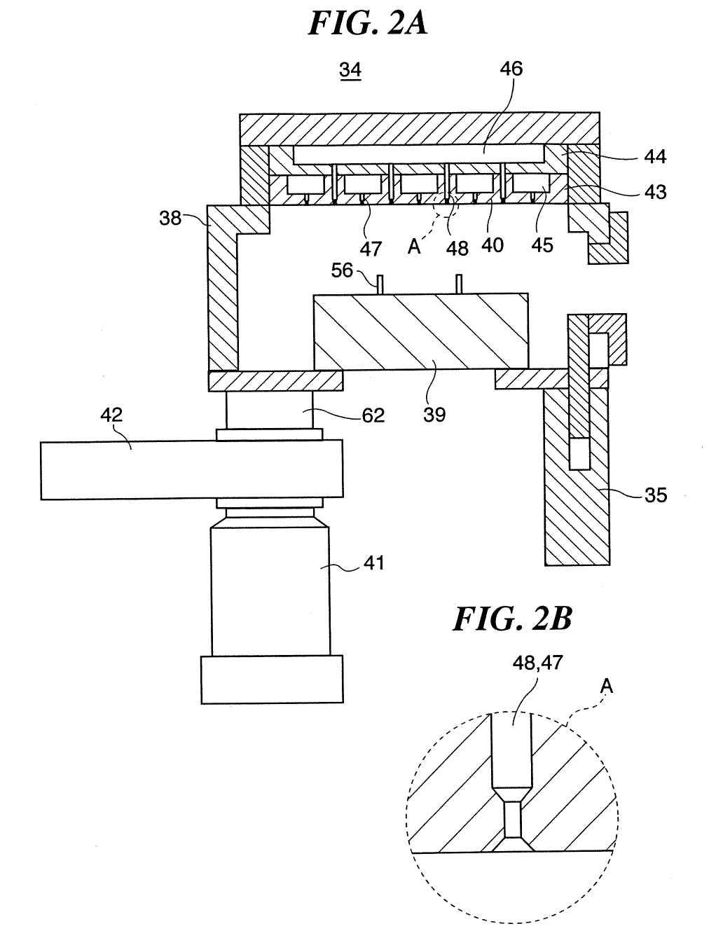

FIGS. 2A and 2B are sectional views of the second processing unit 34 appearing in FIG. 1; specifically, FIG. 2A is a sectional view taken along line II-II in FIG. 1, and FIG. 2B is an enlarged view of a portion A shown in FIG. 2A.

As shown in FIG. 2A, the second processing unit 34 has a cylindrical processing chamber (chamber) 38, an ESC 39 as a wafer W mounting stage disposed in the chamber 38, a shower head 40 disposed above the chamber 38, a TMP (turbo molecular pump) 41 for exhausting gas out from the chamber 38, and an APC (adaptive pressure control) valve 42 that is a variable butterfly valve disposed between the chamber 38 and the TMP 41 for controlling the pressure in the chamber 38.

The ESC 39 has therein an electrode plate (not shown) to which a DC voltage is applied. A wafer W is attracted to and held on the ESC 39 through a Johnsen-Rahbek force or a Coulomb force generated by the DC voltage. Moreover, the ESC 39 also has a coolant chamber (not shown) as a temperature adjusting mechanism. A coolant, for example cooling water or a Galden fluid, at a predetermined temperature is circulated through the coolant chamber. A processing temperature of the wafer W attracted to and held on an upper surface of the ESC 39 is controlled through the temperature of the coolant. Furthermore, the ESC 39 also has a heat-transmitting gas supply system (not shown) that supplies a heat-transmitting gas (helium gas) uniformly between the upper surface of the ESC 39 and a rear surface of the wafer W. The heat-transmitting gas carries out heat exchange between the wafer W and the ESC 39, which is held at a desired specified temperature by the coolant, during the COR, thus cooling the wafer W efficiently and uniformly.

Moreover, the ESC 39 has a plurality of pusher pins 56 as lifting pins that can be made to project out from the upper surface of the ESC 39. The pusher pins 56 are housed inside the ESC 39 when a wafer W is attracted to and held on the ESC 39, and are made to project out from the upper surface of the ESC 39 so as to lift the wafer W up when the wafer W is to be transferred out from the chamber 38 after having been subjected to the COR.

The shower head 40 has a two-layer structure comprised of a lower layer portion 43 and an upper layer portion 44. The lower layer portion 43 has first buffer chambers 45 therein, and the upper layer portion 44 has a second buffer chamber 46 therein. The first buffer chambers 45 and the second buffer chamber 46 are communicated with the interior of the chamber 38 via gas-passing holes 47 and 48 respectively. That is, the shower head 40 is comprised of two plate-shaped members (the lower layer portion 43 and the upper layer portion 44) that are disposed one upon another and have therein internal channels leading into the chamber 38 for gas supplied into the first buffer chambers 45 and the second buffer chamber 46.

When carrying out the COR on a wafer W, NH₃ (ammonia) gas is supplied into the first buffer chambers 45 from an ammonia gas supply pipe 57, described below, and the supplied ammonia gas is then supplied via the gas-passing holes 47 into the chamber 38, and moreover HF (hydrogen fluoride) gas is supplied into the second buffer chamber 46 from a hydrogen fluoride gas supply pipe 58, described below, and the supplied hydrogen fluoride gas is then supplied via the gas-passing holes 48 into the chamber 38.

Moreover, the shower head 40 also has a heater, for example a heating element, (not shown) built therein. The heating element is preferably disposed on the upper layer portion 44, for controlling the temperature of the hydrogen fluoride gas in the second buffer chamber 46.

Moreover, a portion of each of the gas-passing holes 47 and 48 where the gas-passing hole 47 or 48 opens out into the chamber 38 is formed so as to widen out toward an end thereof as shown in FIG. 2B. As a result, the ammonia gas and the hydrogen fluoride gas can be made to diffuse through the chamber 38 efficiently. Furthermore, each of the gas-passing holes 47 and 48 has a cross-sectional shape having a constriction therein. As a result, any deposit produced in the chamber 38 can be prevented from flowing back into the gas-passing holes 47 and 48, and thus the first buffer chambers 45 and the second buffer chamber 46. Alternatively, the gas-passing holes 47 and 48 may each have a spiral shape.

In the second processing unit 34, the COR is carried out on a wafer W by adjusting the pressure in the chamber 38 and the volumetric flow rate ratio between the ammonia gas and the hydrogen fluoride gas. Moreover, the second processing unit 34 is designed such that the ammonia gas and the hydrogen fluoride gas first mix with one another in the chamber 38 (post-mixing design), and hence the two gases are prevented from mixing together until they are introduced into the chamber 38, whereby the hydrogen fluoride gas and the ammonia gas are prevented from reacting with one another before being introduced into the chamber 38.

Moreover, in the second processing unit 34, a heater, for example a heating element, (not shown) is built into a side wall of the chamber 38, whereby the temperature of the atmosphere in the chamber 38 can be prevented from decreasing. As a result, the reproducibility of the COR can be improved. Moreover, the heating element in the side wall also controls the temperature of the side wall, whereby by-products formed in the chamber 38 can be prevented from becoming attached to the inside of the side wall.

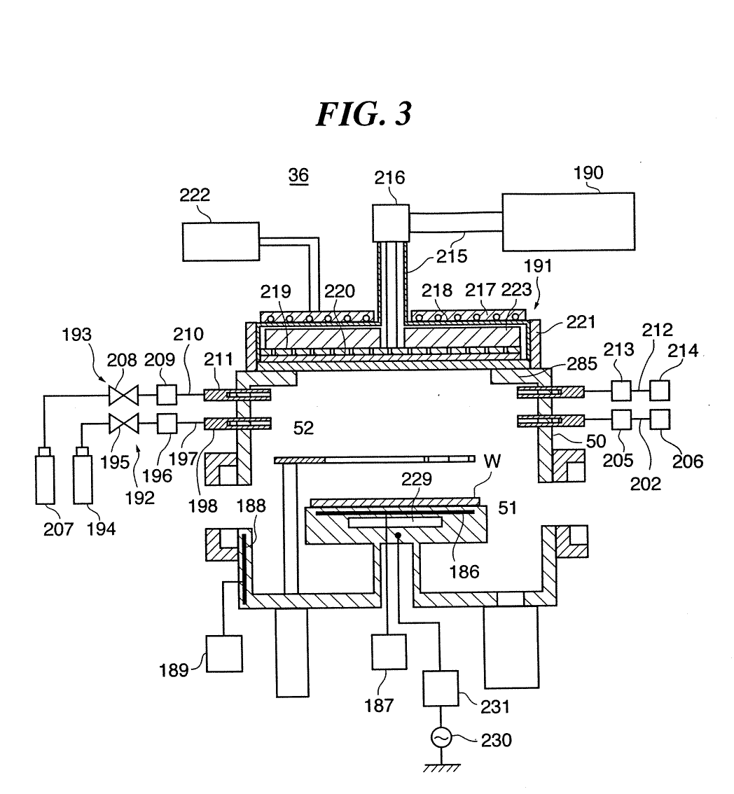

FIG. 3 is a sectional view of the third processing unit 36 appearing in FIG. 1.

As shown in FIG. 3, the third processing unit 36 has a box-shaped processing chamber (chamber) 50, a stage heater 51 as a wafer W mounting stage disposed in the chamber 50 such as to face a ceiling portion 185 of the chamber 50, and a buffer arm 52 that is disposed in the vicinity of the stage heater 51 and lifts up a wafer W mounted on the stage heater 51.

The stage heater 51 is made of aluminum having an oxide film formed on a surface thereof, and heats the wafer W mounted on an upper surface thereof up to a predetermined temperature using a heater 186 comprised of heating wires or the like built therein. Specifically, the stage heater 51 directly heats the wafer W mounted thereon up to 100 to 200° C., preferably approximately 135° C., over at least 1 minute. A heating amount of the heater 186 is controlled by a heater controller 187. Moreover, in addition to the heater 186, the stage heater 51 also has a coolant chamber 229 as a temperature adjusting mechanism. A coolant, for example cooling water or a Galden fluid, at a predetermined temperature is circulated through the coolant chamber 229, whereby the wafer W mounted on the upper surface of the stage heater 51 is cooled down to a predetermined temperature through the temperature of the coolant during the organic layer removal processing. Furthermore, the stage heater 51 also has a heat-transmitting gas supply system (not shown) that supplies a heat-transmitting gas (helium gas) uniformly between the upper surface of the stage heater 51 and a rear surface of the wafer W. The heat-transmitting gas carries out heat exchange between the wafer W and the stage heater 51, which is held at a desired specified temperature by the coolant, during the organic layer removal processing, thus cooling the wafer W efficiently and uniformly.

A cartridge heater 188 is built into a side wall of the chamber 50. The cartridge heater 188 controls the wall surface temperature of the side wall of the chamber 50 to a temperature in a range of 25 to 80° C. As a result, by-products are prevented from becoming attached to the side wall of the chamber 50, whereby particles due to such attached by-products are prevented from arising, and hence the time period between one cleaning and the next of the chamber 50 can be extended. Moreover, an outer periphery of the chamber 50 is covered by a heat shield (not shown), and the heating amount of the cartridge heater 188 is controlled by a heater controller 189.

A sheet heater or a UV radiation heater may also be provided in the ceiling portion 185 as a heater for heating the wafer W from above. An example of a UV radiation heater is a UV lamp that emits UV of wavelength 190 to 400 nm.

After being subjected to the COR, each wafer W is temporarily laid by above a track of a supporting portion 53 of the second transfer arm 37 by the buffer arm 52, whereby swapping over of wafers W in the second processing unit 34 and the third processing unit 36 can be carried out smoothly.

In the third processing unit 36, the PHT is carried out on each wafer W by heating the wafer W.

Moreover, the third processing unit 36 further has a microwave source 190, an antenna apparatus 191 (microwave introducing apparatus), an oxygen gas supply system 192, and a discharge gas supply system 193.

The oxygen gas supply system 192 has an oxygen gas source 194, a valve 195, an MFC (mass flow controller) 196, and an oxygen gas supply line 197 that connects the oxygen gas source 194, the valve 195, and the MFC 196 together. The oxygen gas supply system 192 is connected by the oxygen gas supply line 197 to an oxygen gas supply ring 198 that is made of quartz and is disposed in the side wall of the chamber 50.

During the organic layer removal processing, the oxygen gas source 194 supplies in oxygen gas, the valve 195 is opened, and the MFC 196, which has, for example, a bridge circuit, an amplifying circuit, a comparator controlling circuit, a flow control valve and so on, measures the flow rate of the oxygen gas by detecting heat transport accompanying the flow of the oxygen gas, and controls the flow rate of the oxygen gas using the flow control valve based on the measurement results.

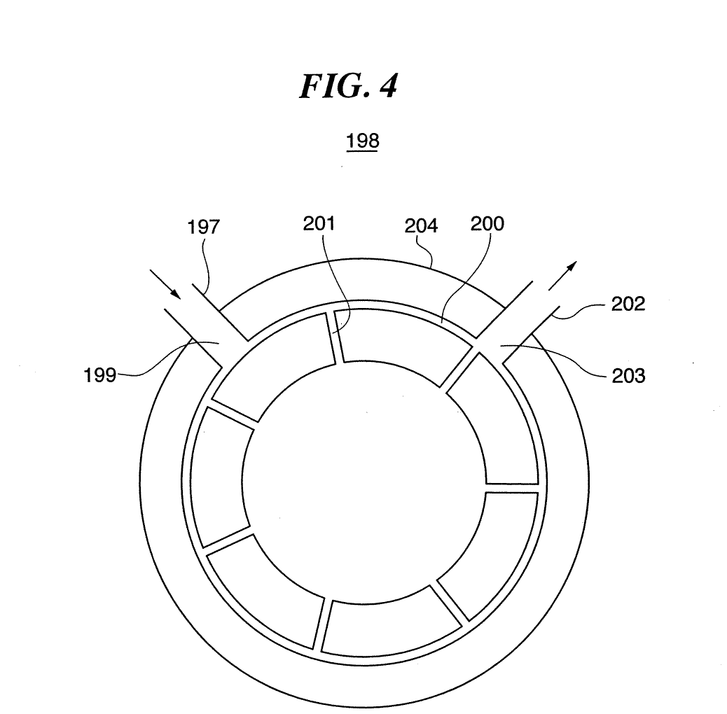

FIG. 4 is a plan view schematically showing the construction of the oxygen gas supply ring 198 appearing in FIG. 3.

As shown in FIG. 4, the oxygen gas supply ring 198 has a ring-shaped main body 204 made of quartz, an inlet 199 connected to the oxygen gas supply line 197, an annular channel 200 connected to the inlet 199, a plurality of oxygen gas supply nozzles 201 connected to the channel 200, and an outlet 203 connected to the channel 200 and a gas discharge line 202, described below. The oxygen gas supply nozzles 201 are disposed at equal intervals along a circumferential direction of the main body 204, whereby a uniform oxygen gas flow is formed in the chamber 50.

The channel 200 and the oxygen gas supply nozzles 201 of the oxygen gas supply ring 198 are connected to the gas discharge line 202, and the gas discharge line 202 is connected via a PCV (pressure control valve) 205 to a vacuum pump 206 such as a TMP, a sputter ion pump, a getter pump, a sorption pump, or a cryopump. (Residual) oxygen gas and moisture in the channel 200 and the oxygen gas supply nozzles 201 can thus be exhausted out from the outlet 203. As a result, residual matter such as (residual) oxygen gas and moisture in the channel 200 and the oxygen gas supply nozzles 201 that is difficult to completely remove using a third processing unit exhaust system 67, described below, can be removed effectively.

The PCV 205 is controlled such as to be closed when the valve 195 is open, and open when the valve 195 is closed. As a result, during the organic layer removal processing for which the valve 195 is open, the vacuum pump 206 is closed, whereby the oxygen gas can be used efficiently in the organic layer removal processing. On the other hand, during a time period when the organic layer removal processing is not being carried out such as after the organic layer removal processing has been completed, the vacuum pump 206 is opened, whereby residual matter in the channel 200 and the oxygen gas supply nozzles 201 of the oxygen gas supply ring 198 is exhausted reliably. As a result, ununiform introduction of the oxygen gas from the oxygen gas supply nozzles 201 due to the presence of residual matter can be prevented from arising when the organic layer removal processing is subsequently carried out again, and moreover attachment of the residual matter itself onto a wafer W can be prevented.

The discharge gas supply system 193 has a discharge gas source 207, a valve 208, an MFC 209, and a discharge gas supply line 210 that connects the discharge gas source 207, the valve 208, and the MFC 209 together. The discharge gas supply system 193 is connected by the discharge gas supply line 210 to a discharge gas supply ring 211 that is made of quartz and is disposed in the side wall of the chamber 50.

During the organic layer removal processing, the discharge gas source 207 supplies in a discharge gas, for example a gas comprised of a noble gas (neon gas, xenon gas, argon gas, helium gas, radon gas, or krypton gas) mixed with N₂ and H₂. The valve 208, the MFC 209, the discharge gas supply line 210, and the discharge gas supply ring 211 have a similar construction to the valve 195, the MFC 196, the oxygen gas supply line 197, and the oxygen gas supply ring 198 respectively, and hence description thereof is omitted.

Moreover, a channel and discharge gas supply nozzles (neither shown) in the discharge gas supply ring 211 are connected to a gas discharge line 212, and the gas discharge line 212 is connected via a PCV 213 to a vacuum pump 214. The gas discharge line 212, the PCV 213, and the vacuum pump 214 have a similar construction to the gas discharge line 202, the PCV 205, and the vacuum pump 206 respectively, and hence description thereof is omitted.

The microwave source 190 is comprised of, for example, a magnetron, and generally produces 2.45 GHz microwaves at a power output of, for example, 5 kW. The microwave source 190 is connected to the antenna apparatus 191 via a waveguide 215. A mode converter 216 is disposed part way along the waveguide 215. The mode converter 216 converts the transmission mode of the microwaves produced by the microwave source 190 into a TM, TE, or TEM mode or the like. Note that an isolator that absorbs microwaves that are reflected back toward the magnetron, and an EH tuner or a stub tuner are omitted from FIG. 3.

The antenna apparatus 191 has a disk-shaped temperature control plate 217, a cylindrical housing member 218, a disk-shaped slot electrode 219 (antenna), a disk-shaped dielectric plate 220, an annular electromagnetic wave absorber 221 that surrounds a side surface of the housing member 218, a temperature controller 222 connected to the temperature control plate 217, and a disk-shaped wave retarding member 223.

The housing member 218 has the temperature control plate 217 mounted on an upper portion thereof, and has housed therein the wave retarding member 223 and the slot electrode 219, which contacts a lower portion of the wave retarding member 223. The dielectric plate 220 is disposed below the slot electrode 219. The housing member 218 and the wave retarding member 223 are each made of a material having a high thermal conductivity, and hence are each at approximately the same temperature as the temperature control plate 217.

The wave retarding member 223 is made of a predetermined material having a high thermal conductivity and having a predetermined permittivity so as to shorten the wavelength of the microwaves. Moreover, to make the density of the microwaves introduced into the chamber 50 uniform, a large number of slits 224, described below, must be formed in the slot electrode 219; due to the wave retarding member 223 shortening the wavelength of the microwaves, it is possible to form a large number of such slits 224 in the slot electrode 219.

As the material of the wave retarding member 223, it is preferable to use, for example, an alumina ceramic, SiN, or AlN. For example, AlN has a relative permittivity et of approximately 9, and hence the wavelength shortening factor n, which is given by 1/(εₜ)^{1/2}, is approximately 0.33. The velocity and wavelength of the microwaves passing through the wave retarding member 223 are thus each multiplied by approximately 0.33, and hence the spacing between the slits 224 in the slot electrode 219 can be reduced, whereby a larger number of the slits 224 can be formed in the slot electrode 219.

The slot electrode 219 is screwed onto the wave retarding member 223, and is comprised of, for example, a copper plate of diameter 50 cm and thickness not more than 1 mm. The slot electrode 219 is known as a radial line slot antenna (RLSA) (or ultra-high performance flat antenna) in the technical field to which the present invention pertains. Note that in the present embodiment, an antenna of a form other than an RLSA, for example a single layer structure waveguide flat antenna or a dielectric substrate parallel plate slot array may be used instead.

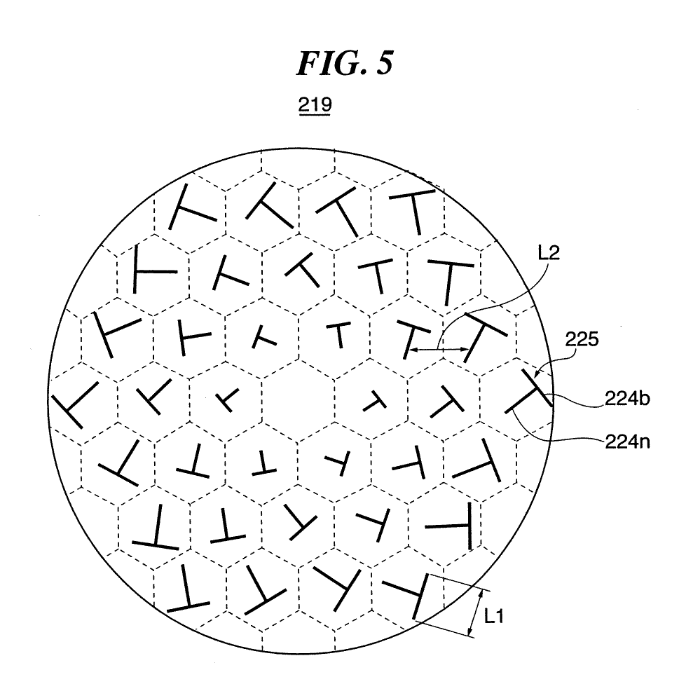

FIG. 5 is a plan view schematically showing the construction of the slot electrode 219 appearing in FIG. 3.

As shown in FIG. 5, a surface of the slot electrode 219 is divided into a plurality of hypothetical regions having the same area as one another, and in each region there is a slit pair 225 comprised of slits 224a and 224b. The density of the slit pairs 225 is thus substantially constant over the surface of the slot electrode 219. The ion energy is thus distributed uniformly over a surface of the dielectric plate 220 disposed below the slot electrode 219, and hence liberation of a chemical element from the dielectric plate 220 due to ununiform distribution of the ion energy can be prevented from occurring. As a result, contamination of the oxygen gas with a chemical element liberated from the dielectric plate 220 as an impurity can be prevented, and hence the wafers W can be subjected to high-quality organic layer removal processing.

The slits 224a and 224b in each slit pair 225 are disposed substantially in a T-shape, and moreover are very slightly separated from one another.

Each of the slits 224a and 224b has a length L1 set within a range between approximately 0.5 times the wavelength λ of the microwaves in the waveguide 215 (hereinafter referred to as the “guide wavelength”) and approximately 2.5 times the wavelength of the microwaves in free space, and has a width set to approximately 1 mm; the spacing L2 between adjacent slit pairs 225 is set to be approximately equal to the guide wavelength λ. Specifically, the length L1 of each of the slits 224a and 224b is set to be within a range given by the following formula.

(λ₀/2)×{1/(εₜ)^{1/2}}≦L1≦λ₀×2.5, where εₜ represents relative permittivity.

Each of the slits 224a and 224b is disposed such as to obliquely cross a radial line from the center of the slot electrode 219 at 45°. Moreover, the size of the slits 224a and 224b in each slit pair 225 increases with increasing distance from the center of the slot electrode 219. For example, the size of the slits 224a and 224b in a slit pair 225 disposed at a predetermined distance from the center is set to be in a range of 1.2 to 2 times the size of the slits 224a and 224b in a slit pair 225 disposed at half of this predetermined distance from the center.

Note that so long as the density of the slit pairs can be made to be substantially constant over the surface of the slot electrode 219, the shape and arrangement of the slits 224 are not limited to being as described above, and moreover the shape of each of the divided regions is not limited to being as described above. For example, the regions may have the same shape as one another, or may have different shapes. Moreover, even in the case that the regions have the same shape as one another, this shape is not limited to being hexagonal, but rather any shape may be used, for example triangular or square. Moreover, the slit pairs 225 may alternatively be arranged in concentric circles or in a spiral manner.

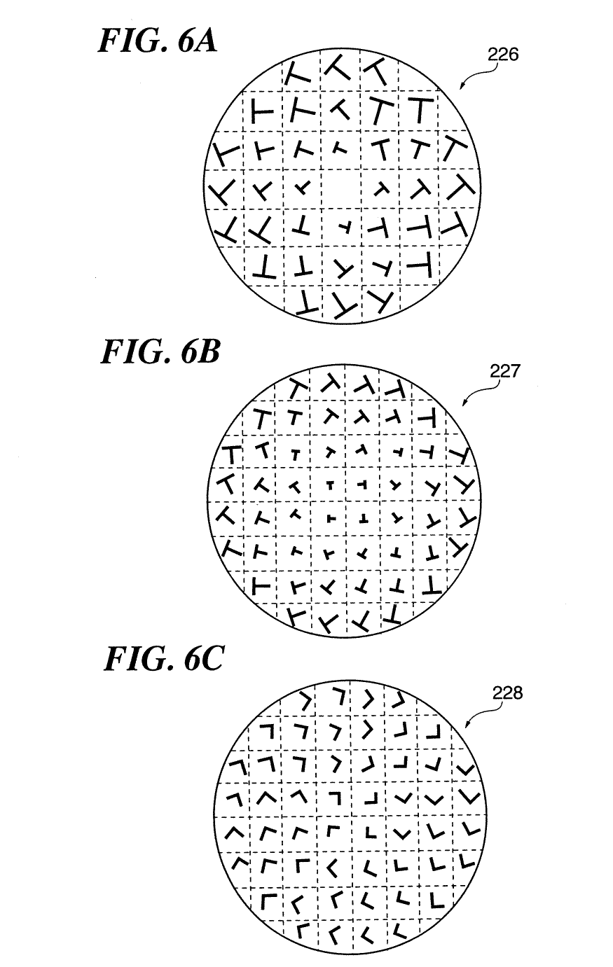

The slot electrode used in the present embodiment is not limited to the slot electrode 219 shown in FIG. 5, but rather a slot electrode 226, a slot electrode 227, or a slot electrode 228 as shown in FIGS. 6A to 6C respectively may also be used. For each of the slot electrodes 226 to 228 shown in FIGS. 6A to 6C, the regions are square. Each of the slot electrodes 226 and 227 has T-shaped slit pairs 225, but differ in terms of the dimensions and arrangement of the slits 224. For the slot electrode 228, the two slits in each slit pair 225 are disposed such as to form a V-shape.

Moreover, the annular electromagnetic wave absorber 221 is comprised of a microwave power reflection preventing radiating element of width approximately several mm disposed such as to surround a peripheral portion of the slot-electrode 219, and thus the side surface of the housing member 218. The electromagnetic wave absorber 221 absorbs standing waves (transverse waves) in the microwaves from the slot electrode 219 so that emission of such standing waves can be suppressed, whereby the distribution of the microwaves in the chamber 50 can be prevented from being disturbed by standing waves, and moreover the antenna efficiency of the slot electrode 219 can be improved.

The temperature controller 222 has a heater and a temperature sensor (neither shown) connected to the temperature control plate 217, and controls the temperature of the temperature control plate 217 to be a predetermined temperature by adjusting the flow rate and temperature of cooling water or another coolant (an alcohol, a Galden fluid, a freon, etc.) introduced into the temperature control plate 217. The temperature control plate 217 is made of a material that has a high thermal conductivity and can readily have a channel formed therein, for example stainless steel. The wave retarding member 223 and the slot electrode 219 contact the temperature control plate 217 via the housing member 218, and hence the temperature of each of the wave retarding member 223 and the slot electrode 219 is controlled by the temperature control plate 217. The temperature of each of the wave retarding member 223 and the slot electrode 219, which are heated up by the microwaves, can thus be controlled to a desired temperature, and as a result the wave retarding member 223 and the slot electrode 219 can be prevented from deforming through thermal expansion, and hence an ununiform distribution of the microwaves in the chamber 50 due to such deformation of the wave retarding member 223 and the slot electrode 219 can be prevented from occurring. Due to the above, a decrease in the quality of the organic layer removal processing due to an ununiform microwave distribution can be prevented.

The dielectric plate 220 is made of an insulating material, and is disposed between the slot electrode 219 and the chamber 50. The slot electrode 219 and the dielectric plate 220 have surfaces thereof joined together firmly and hermetically using, for example, a wax. Alternatively, it is also possible to form a slot electrode 219 containing slits by printing a thin copper film by screen printing or the like on a rear surface of a dielectric plate 220 made of a fired ceramic or aluminum nitride (AlN).

The dielectric plate 220 prevents deformation of the slot electrode 219 due to the low pressure in the chamber 50, and sputtering away of or copper contamination of the slot electrode 219. Moreover, because the dielectric plate 220 is made of an insulating material, the microwaves from the slot electrode 219 pass through the dielectric plate 220 and are thus introduced into the chamber 50. Furthermore, the dielectric plate 220 may be made of a material having a low thermal conductivity, whereby the slot electrode 219 can be prevented from being affected by the temperature in the chamber 50.

In the present embodiment, the thickness of the dielectric plate 220 is set to be within a range of 0.5 to 0.75 times, preferably approximately 0.6 to approximately 0.7 times, the wavelength of the microwaves passing through the dielectric plate 220. Microwaves of a frequency 2.45 GHz have a wavelength of approximately 122.5 mm in a vacuum. In the case that the dielectric plate 220 is made of AlN, as described above the relative permittivity εₜ is approximately 9 and hence the wavelength shortening factor is approximately 0.33, and thus the wavelength of the microwaves in the dielectric plate 220 is approximately 40.8 mm. In the case that the dielectric plate 220 is made of AlN, the thickness of the dielectric plate 220 is thus set to be within a range of approximately 20.4 to approximately 30.6 mm, preferably approximately 24.5 to approximately 28.6 mm. More generally, the thickness H of the dielectric plate 220 preferably satisfies 0.5λ<H<0.75λ, more preferably 0.6λ≦H≦0.7λ, wherein λ is the wavelength of the microwaves passing through the dielectric plate 220. Here, the wavelength λ of the microwaves passing through the dielectric plate 220 is given by λ=λ₀×n, wherein λ₀ is the wavelength of the microwaves in a vacuum, and the wavelength shortening factor n is given by 1/(εₜ)^{1/2}.

The stage heater 51 has connected thereto a biasing radio frequency power source 230 and a matching box 231. The biasing radio frequency power source 230 applies a negative DC bias (e.g. 13.56 MHz radio frequency) to the wafer W. The stage heater 51 thus acts as a lower electrode. The matching box 231 has variable condensers arranged in parallel and series, and prevents the effects of electrode stray capacitance and stray inductance in the chamber 50, and also carries out load matching. Moreover, upon the negative DC bias being applied to the wafer W, ions are accelerated toward the wafer W by the bias voltage, whereby processing by the ions is promoted. The ion energy is determined by the bias voltage, and the bias voltage can be controlled by the radio frequency electrical power applied from the biasing radio frequency power source 230. The frequency of the radio frequency electrical power applied by the biasing radio frequency power source 230 can be adjusted in accordance with the shape, number and distribution of the slits 224 in the slot electrode 219.

The interior of the chamber 50 is held at a desired low pressure, for example a vacuum, by the third processing unit exhaust system 67. The third processing unit exhaust system 67 uniformly exhausts the interior of the chamber 50, whereby the plasma density in the chamber 50 is kept uniform. The third processing unit exhaust system 67 has, for example, a TMP and a DP (dry pump) (neither shown), the DP being connected to the chamber 50 via a PCV (not shown) and an APC valve 69. The PCV may be, for example, a conductance valve, a gate valve, a high vacuum valve, or the like.

In the third processing unit 36 described above, each wafer W that has been subjected to the PHT is subjected to the organic layer removal processing following on from the PHT.

Returning to FIG. 1, the second load lock unit 49 has a box-shaped transfer chamber (chamber) 70 containing the second transfer arm 37. The internal pressure of each of the second processing unit 34 and the third processing unit 36 is held at vacuum or a pressure below atmosphere pressure, whereas the internal pressure of the loader unit 13 is held at atmospheric pressure. The second load lock unit 49 is thus provided with a vacuum gate valve 54 in a connecting part between the second load lock unit 49 and the third processing unit 36, and an atmospheric door valve 55 in a connecting part between the second load lock unit 49 and the loader unit 13, whereby the second load lock unit 49 is constructed as a preliminary vacuum transfer chamber whose internal pressure can be adjusted.

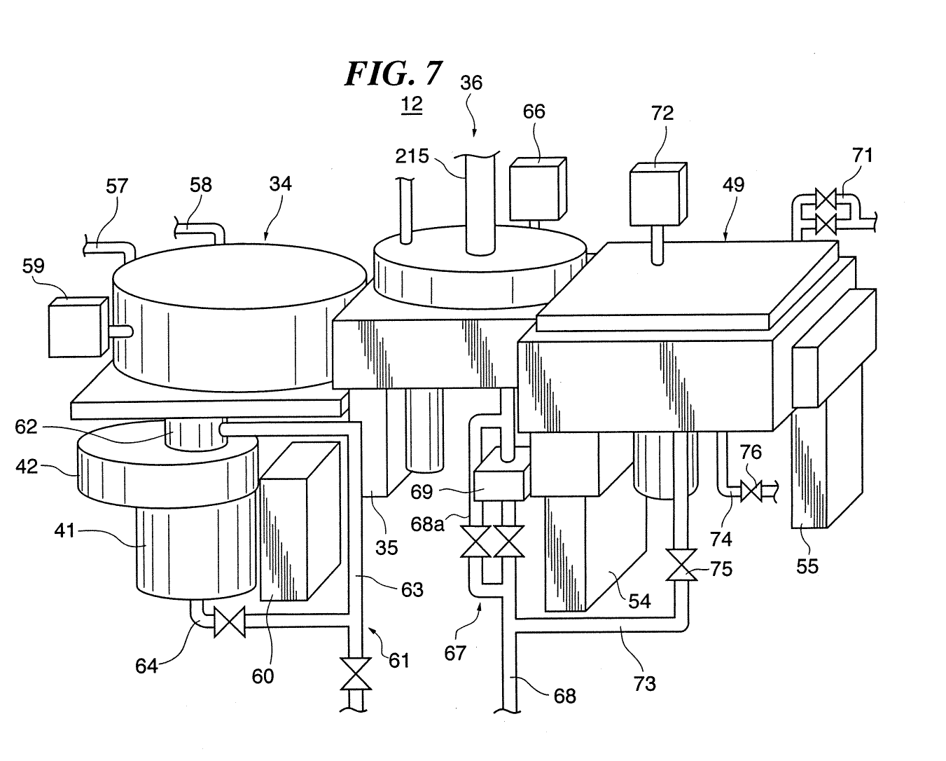

FIG. 7 is a perspective view schematically showing the construction of the second process ship 12 appearing in FIG. 1.

As shown in FIG. 7, the second processing unit 34 has the ammonia gas supply pipe 57 for supplying ammonia gas into the first buffer chambers 45, the hydrogen fluoride gas supply pipe 58 for supplying hydrogen fluoride gas into the second buffer chamber 46, a pressure gauge 59 for measuring the pressure in the chamber 38, and a chiller unit 60 that supplies a coolant into the cooling system provided in the ESC 39.

The ammonia gas supply pipe 57 has provided therein an MFC (not shown) for adjusting the flow rate of the ammonia gas supplied into the first buffer chambers 45, and the hydrogen fluoride gas supply pipe 58 has provided therein an MFC (not shown) for adjusting the flow rate of the hydrogen fluoride gas supplied into the second buffer chamber 46. The MFC in the ammonia gas supply pipe 57 and the MFC in the hydrogen fluoride gas supply pipe 58 operate collaboratively so as to adjust the volumetric flow rate ratio between the ammonia gas and the hydrogen fluoride gas supplied into the chamber 38.

Moreover, a second processing unit exhaust system 61 connected to a DP (not shown) is disposed below the second processing unit 34. The second processing unit exhaust system 61 is for exhausting gas out from the chamber 38, and has an exhaust pipe 63 that is communicated with an exhaust duct 62 provided between the chamber 38 and the APC valve 42, and an exhaust pipe 64 connected below (i.e. on the exhaust side) of the TMP 41. The exhaust pipe 64 is connected to the exhaust pipe 63 upstream of the DP.

The third processing unit 36 has a pressure gauge 66 for measuring the pressure in the chamber 50, and the third processing unit exhaust system 67 which is for exhausting nitrogen gas or the like out from the chamber 50.

The third processing unit exhaust system 67 has a main exhaust pipe 68 that is communicated with the chamber 50 and is connected to a DP (not shown), the APC valve 69 which is disposed part way along the main exhaust pipe 68, and an auxiliary exhaust pipe 68a that branches off from the main exhaust pipe 68 so as to circumvent the APC valve 69 and is connected to the main exhaust pipe 68 upstream of the DP. The APC valve 69 controls the pressure in the chamber 50.

The second load lock unit 49 has a nitrogen gas supply pipe 71 for supplying nitrogen gas into the chamber 70, a pressure gauge 72 for measuring the pressure in the chamber 70, a second load lock unit exhaust system 73 for exhausting the nitrogen gas out from the chamber 70, and an external atmosphere communicating pipe 74 for releasing the interior of the chamber 70 to the external atmosphere.

The nitrogen gas supply pipe 71 has provided therein an MFC (not shown) for adjusting the flow rate of the nitrogen gas supplied into the chamber 70. The second load lock unit exhaust system 73 is comprised of a single exhaust pipe, which is communicated with the chamber 70 and is connected to the main exhaust pipe 68 of the third processing unit exhaust system 67 upstream of the DP. Moreover, the second load lock unit exhaust system 73 has an openable/closable exhaust valve 75 therein, and the external atmosphere communicating pipe 74 has an openable/closable relief valve 76 therein. The exhaust valve 75 and the relief valve 76 are operated collaboratively so as to adjust the pressure in the chamber 70 to any pressure from atmospheric pressure to a desired degree of vacuum.

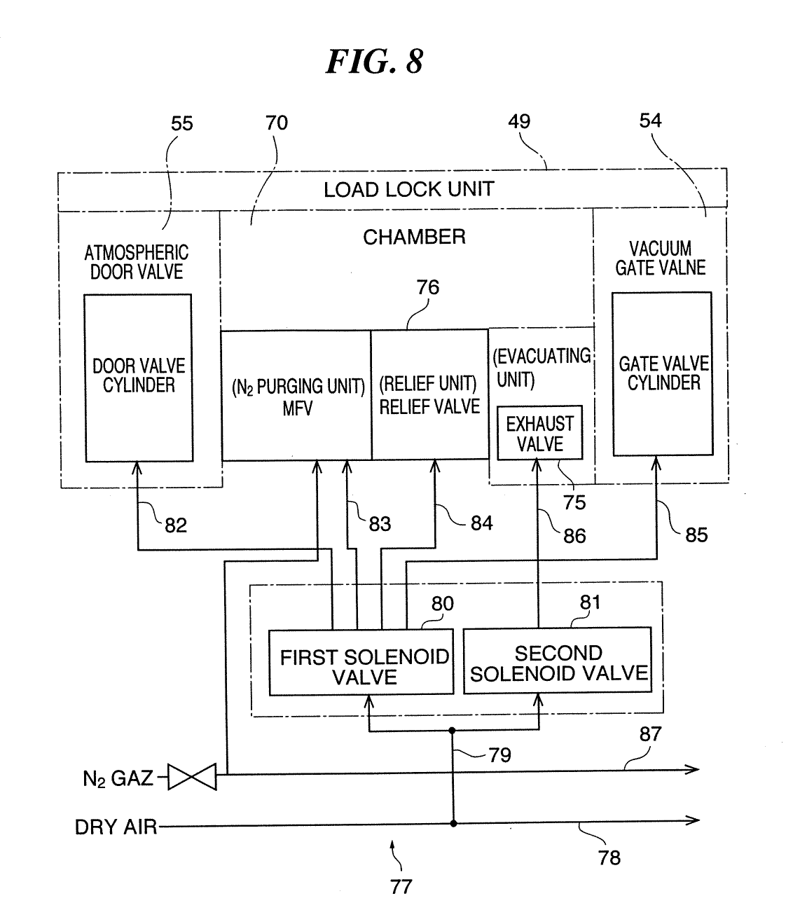

FIG. 8 is a diagram schematically showing the construction of a unit-driving dry air supply system for the second load lock unit 49 appearing in FIG. 7.

As shown in FIG. 8, dry air from the unit-driving dry air supply system 77 for the second load lock unit 49 is supplied to a door valve cylinder for driving a sliding door of the atmospheric door valve 55, the MFC in the nitrogen gas supply pipe 71 as an N₂ purging unit, the relief valve 76 in the external atmosphere communicating pipe 74 as a relief unit for releasing the interior of the chamber 70 to the external atmosphere, the exhaust valve 75 in the second load lock unit exhaust system 73 as an evacuating unit, and a gate valve cylinder for driving a sliding gate of the vacuum gate valve 54.

The unit-driving dry air supply system 77 has an auxiliary dry air supply pipe 79 that branches off from a main dry air supply pipe 78 of the second process ship 12, and a first solenoid valve 80 and a second solenoid valve 81 that are connected to the auxiliary dry air supply pipe 79.

The first solenoid valve 80 is connected respectively to the door valve cylinder, the MFC, the relief valve 76, and the gate valve cylinder by dry air supply pipes 82, 83, 84, and 85, and controls operation of these elements by controlling the amount of dry air supplied thereto. Moreover, the second solenoid valve 81 is connected to the exhaust valve 75 by a dry air supply pipe 86, and controls operation of the exhaust valve 75 by controlling the amount of dry air supplied to the exhaust valve 75. The MFC in the nitrogen gas supply pipe 71 is also connected to a nitrogen (N₂) gas supply system 87.

The second processing unit 34 and the third processing unit 36 also each has a unit-driving dry air supply system having a similar construction to the unit-driving dry air supply system 77 for the second load lock unit 49 described above.

Returning to FIG. 1, the substrate processing apparatus 10 has a system controller for controlling operations of the first process ship 11, the second process ship 12 and the loader unit 13, and an operation panel 88 that is disposed at one end of the loader unit 13 in the longitudinal direction of the loader unit 13.

The operation panel 88 has a display section comprised of, for example, an LCD (liquid crystal display), for displaying the state of operation of the component elements of the substrate processing apparatus 10.

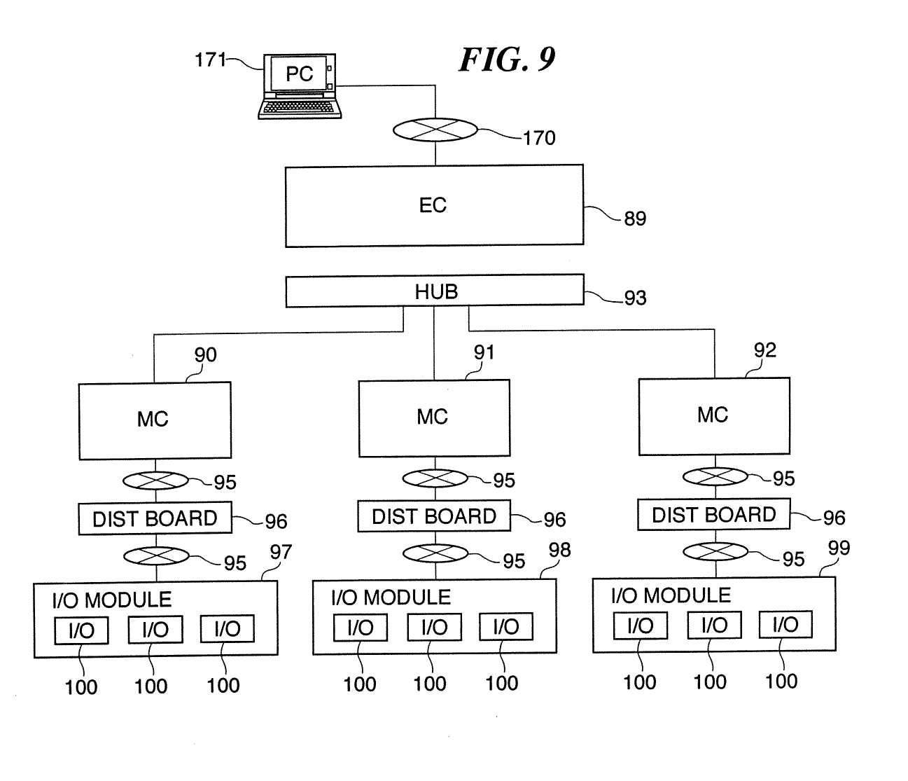

Moreover, as shown in FIG. 9, the system controller is comprised of an EC (equipment controller) 89, three MC's (module controllers) 90, 91 and 92, and a switching hub 93 that connects the EC 89 to each of the MC's. The EC 89 of the system controller is connected via a LAN (local area network) 170 to a PC 171, which is an MES (manufacturing execution system) that carries out overall control of the manufacturing processes in the manufacturing plant in which the substrate processing apparatus 10 is installed. In collaboration with the system controller, the MES feeds back real-time data on the processes in the manufacturing plant to a basic work system (not shown), and makes decisions relating to the processes in view of the overall load on the manufacturing plant and so on.

The EC 89 is a master controller (main controller) that controls the MC's and carries out overall control of the operation of the substrate processing apparatus 10. The EC 89 has a CPU, a RAM, an HDD and so on. The CPU sends control signals to the MC's in accordance with programs corresponding to wafer W processing methods, i.e. recipes, specified by a user using the operation panel 88, thus controlling the operations of the first process ship 11, the second process ship 12 and the loader unit 13.

The switching hub 93 switches which MC is connected to the EC 89 in accordance with the control signals from the EC 89.

The MC's 90, 91 and 92 are slave controllers (auxiliary controllers) that control the operations of the first process ship 11, the second process ship 12, and the loader unit 13 respectively. Each of the MC's is connected respectively to an I/O (input/output) module 97, 98 or 99 through a DIST (distribution) board 96 via a GHOST network 95. Each GHOST network 95 is a network that is realized through an LSI known as a GHOST (general high-speed optimum scalable transceiver) on an MC board of the corresponding MC. A maximum of 31 I/O modules can be connected to each GHOST network 95; with respect to the GHOST network 95, the MC is the master, and the I/O modules are slaves.

The I/O module 98 is comprised of a plurality of I/O units 100 that are connected to component elements (hereinafter referred to as “end devices”) of the second process ship 12, and transmits control signals to the end devices and output signals from the end devices. Examples of the end devices connected to the I/O units 100 of the I/O module 98 are: in the second processing unit 34, the MFC in the ammonia gas supply pipe 57, the MFC in the hydrogen fluoride gas supply pipe 58, the pressure gauge 59, and the APC valve 42; in the third processing unit 36, the MFC 196, the MFC 209, the microwave source 190, the pressure gauge 66, the APC valve 69, the buffer arm 52, and the stage heater 51; in the second load lock unit 49, the MFC in the nitrogen gas supply pipe 71, the pressure gauge 72, and the second transfer arm 37; and in the unit-driving dry air supply system 77, the first solenoid valve 80, and the second solenoid valve 81.

Each of the I/O modules 97 and 99 has a similar construction to the I/O module 98. Moreover, the connection between the I/O module 97 and the MC 90 for the first process ship 11, and the connection between the I/O module 99 and the MC 92 for the loader unit 13 are constructed similarly to the connection between the I/O module 98 and the MC 91 described above, and hence description thereof is omitted.

Each GHOST network 95 is also connected to an I/O board (not shown) that controls input/output of digital signals, analog signals and serial signals to/from the I/O units 100.

In the substrate processing apparatus 10, when carrying out the COR on a wafer W, the CPU of the EC 89 implements the COR in the second processing unit 34 by sending control signals to desired end devices via the switching hub 93, the MC 91, the GHOST network 95, and the I/O units 100 of the I/O module 98, in accordance with a program corresponding to a recipe for the COR.

Specifically, the CPU sends control signals to the MFC in the ammonia gas supply pipe 57 and the MFC in the hydrogen fluoride gas supply pipe 58 so as to adjust the volumetric flow rate ratio between the ammonia gas and the hydrogen fluoride gas in the chamber 38 to a desired value, and sends control signals to the TMP 41 and the APC valve 42 so as to adjust the pressure in the chamber 38 to a desired value. Moreover, at this time, the pressure gauge 59 sends the value of the pressure in the chamber 38 to the CPU of the EC 89 in the form of an output signal, and the CPU determines control parameters for the MFC in the ammonia gas supply pipe 57, the MFC in the hydrogen fluoride gas supply pipe 58, the APC valve 42, and the TMP 41 based on the sent value of the pressure in the chamber 38.

Moreover, when carrying out the PHT on a wafer W, the CPU of the EC 89 implements the PHT in the third processing unit 36 by sending control signals to desired end devices in accordance with a program corresponding to a recipe for the PHT.

Specifically, the CPU sends control signals to the APC valve 69 so as to adjust the pressure in the chamber 50 to a desired value, and sends control signals to the stage heater 51 so as to adjust the temperature of the wafer W to a desired temperature. Moreover, at this time, the pressure gauge 66 sends the value of the pressure in the chamber 50 to the CPU of the EC 89 in the form of an output signal, and the CPU determines control parameters for the APC valve 69 based on the sent value of the pressure in the chamber 50.

Furthermore, when carrying out the organic layer removal processing on a wafer W, the CPU of the EC 89 implements the organic layer removal processing in the third processing unit 36 by sending control signals to desired end devices in accordance with a program corresponding to a recipe for the organic layer removal processing.

Specifically, the CPU sends control signals to the MFC 196 and the MFC 209 so as to introduce oxygen gas and the discharge gas into the chamber 50, sends control signals to the APC valve 69 so as to adjust the pressure in the chamber 50 to a desired value, sends control signals to the stage heater 51 so as to adjust the temperature of the wafer W to a desired temperature, and sends control signals to the microwave source 190 so as to introduce microwaves into the chamber 50 from the slot electrode 219 of the antenna apparatus 191. Moreover, at this time, for example the pressure gauge 66 sends the value of the pressure in the chamber 50 to the CPU of the EC 89 in the form of an output signal, and the CPU determines control parameters for the APC valve 69 based on the sent value of the pressure in the chamber 50.

According to the system controller shown in FIG. 9, the plurality of end devices are not directly connected to the EC 89, but rather the I/O units 100 which are connected to the plurality of end devices are modularized to form the I/O modules, and each I/O module is connected to the EC 89 via an MC and the switching hub 93. As a result, the communication system can be simplified.

Moreover, each of the control signals sent by the CPU of the EC 89 contains the address of the I/O unit 100 connected to the desired end device, and the address of the I/O module containing that I/O unit 100. The switching hub 93 thus refers to the address of the I/O module in the control signal, and then the GHOST of the appropriate MC refers to the address of the I/O unit 100 in the control signal, whereby the need for the switching hub 93 or the MC to ask the CPU for the destination of the control signal can be eliminated, and hence smoother transmission of the control signals can be realized.

As described earlier, as a result of etching floating gates and an inter-layer SiO₂ film on a wafer W, a deposit film comprised of an SiOBr layer, a CF-type deposit layer, and an SiOBr layer is formed on side surfaces of trenches formed in the wafer W. As described earlier, each SiOBr layer is a pseudo-SiO₂ layer having properties similar to those of an SiO₂ layer. The SiOBr layers and the CF-type deposit layer cause problems for electronic devices such as continuity defects, and hence must be removed.

In the substrate processing method according to present embodiment, to achieve this, the wafer W having the deposit film formed on the side surfaces of the trenches is subjected to COR, PHT, and organic layer removal processing.

In the substrate processing method according to the present embodiment, ammonia gas and hydrogen fluoride gas are used in the COR. Here, the hydrogen fluoride gas promotes corrosion of the pseudo-SiO₂ layer, and the ammonia gas is involved in synthesis of a reaction by-product for restricting, and ultimately stopping, the reaction between the oxide film and the hydrogen fluoride gas as required. Specifically, the following chemical reactions are used in the COR and the PHT in the substrate processing method according to the present embodiment.

COR

SiO₂+4HF→SiF₄+2H₂O↑

SiF₄+2NH₃+2HF→(NH₄)₂SiF₆

PHT

(NH₄)₂SiF₆→SiF₄↑+2NH₃↑+2HF↑

Small amounts of N₂ and H₂ are also produced in the PHT.

Moreover, in the substrate processing method according to the present embodiment, oxygen radicals produced from oxygen gas are used in the organic layer removal processing. Here, for a wafer W that has been subjected to the COR and the PHT, the SiOBr layer that is the outermost layer of the deposit film on the side surfaces of the trenches has been removed so as to expose the CF-type deposit layer which is an organic layer. The oxygen radicals decompose the exposed CF-type deposit layer. Specifically, the CF-type deposit layer exposed to the oxygen radicals is decomposed through chemical reaction into CO, CO₂, F₂ and so on. As a result, the CF-type deposit layer of the deposit film on the side surfaces of the trenches is removed.

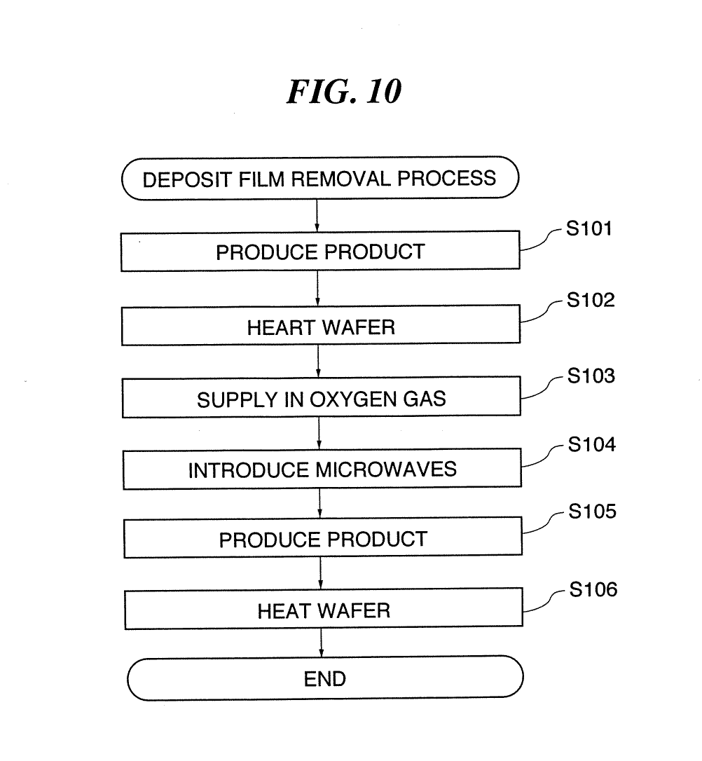

FIG. 10 is a flowchart of a deposit film removal process as the substrate processing method according to the present embodiment.

As shown in FIG. 10, using the substrate processing apparatus 10, first, a wafer W having a deposit film comprised of an SiOBr layer, a CF-type deposit layer, and an SiOBr layer formed on side surfaces of trenches is housed in the chamber 38 of the second processing unit 34, the pressure in the chamber 38 is adjusted to a predetermined pressure, ammonia gas, hydrogen fluoride gas, and argon (Ar) gas as a diluent gas are introduced into the chamber 38 to produce an atmosphere of a mixed gas comprised of ammonia gas, hydrogen fluoride gas and argon gas in the chamber 38, and the outermost SiOBr layer is exposed to the mixed gas under the predetermined pressure. As a result, a product having a complex structure ((NH₄)₂SiF₆) is produced through chemical reaction between the SiOBr layer, the ammonia gas, and the hydrogen fluoride gas (step S101) (chemical reaction processing step). Here, the time for which the outermost SiOBr layer is exposed to the mixed gas is preferably in a range of 2 to 3 minutes, and the temperature of the ESC 39 is preferably set to be in a range of 10 to 100° C.

The partial pressure of the hydrogen fluoride gas in the chamber 38 is preferably in a range of 6.7 to 13.3 Pa (50 to 100 mTorr). As a result, the flow rate ratio for the mixed gas in the chamber 38 is stable, and hence production of the product can be promoted. Moreover, the higher the temperature, the less prone by-products formed in the chamber 38 are to become attached to an inner wall of the chamber 38, and hence the temperature of the inner wall of the chamber 38 is preferably set to 50° C. using the heater (not shown) embedded in the side wall of the chamber 38.

Next, the wafer W on which the product has been produced is mounted on the stage heater 51 in the chamber 50 of the third processing unit 36, the pressure in the chamber 50 is adjusted to a predetermined pressure, nitrogen gas is introduced from the discharge gas supply ring 211 into the chamber 50 to produce viscous flow, and the wafer W is heated to a predetermined temperature using the stage heater 51 (step S102) (heat treatment step). Here, the complex structure of the product is thermally decomposed, the product being separated into silicon tetrafluoride (SiF₄), ammonia and hydrogen fluoride, which are vaporized. The vaporized gas molecules are entrained in the viscous flow of nitrogen gas introduced into the chamber 50, and thus discharged from the chamber 50 by the third processing unit exhaust system 67.

In the third processing unit 36, because the product is a complex compound containing coordinate bonds, and such a complex compound is weakly bonded together and thus undergoes thermal decomposition even at a relatively low temperature, the predetermined temperature to which the wafer W is heated is preferably in a range of 80 to 200° C., and furthermore the time for which the wafer W is subjected to the PHT is preferably in a range of 30 to 120 seconds. Moreover, to produce viscous flow in the chamber 50, it is undesirable to make the degree of vacuum in the chamber 50 high, and moreover a gas flow of a certain flow rate is required. The predetermined pressure in the chamber 50 is thus preferably in a range of 6.7×10 to 1.3×10² Pa (500 mTorr to 1 Torr), and the nitrogen gas flow rate is preferably in a range of 500 to 3000 SCCM. As a result, viscous flow can be produced reliably in the chamber 50, and hence the gas molecules produced through the thermal decomposition of the product can be reliably removed.

Next, a discharge gas is supplied into the chamber 50 of the third processing unit 36 from the discharge gas supply system 193 via the discharge gas supply ring 211 at a predetermined flow rate, and oxygen gas is supplied into the chamber 50 from the oxygen gas supply system 192 via the oxygen gas supply ring 198 at a predetermined flow rate. The oxygen gas supply nozzles 201 in the oxygen gas supply ring 198 are opened facing into the center of the chamber 50 as shown in FIG. 4. Moreover, the stage heater 51 is disposed substantially in the center of the chamber 50 when viewed in plan view. The oxygen gas supply ring 198 thus supplies the oxygen gas (oxygen gas supply step) toward an upper portion of the wafer W mounted on the stage heater 51 (step S103).

Next, microwaves from the microwave source 190 are introduced as, for example, a TEM mode onto the wave retarding member 223 via the waveguide 215. The wavelength of the microwaves introduced onto the wave retarding member 223 is shortened upon the microwaves passing through the wave retarding member 223. After passing through the wave retarding member 223, the microwaves are incident on the slot electrode 219, and the slot electrode 219 introduces the microwaves into the chamber 50 from the slit pairs 225. That is, the slot electrode 219 introduces microwaves into the chamber 50 into which the oxygen gas has been supplied (microwave introducing step) (step S104). Here, the oxygen gas onto which the microwaves are applied is excited so that oxygen radicals are produced. The produced oxygen radicals decompose the CF-type deposit layer that has been exposed through the removal of the outermost SiOBr layer into gas molecules such as CO, CO₂, and F₂ through chemical reaction. The gas molecules are entrained in the viscous flow of nitrogen gas supplied in from the discharge gas supply ring 211, and thus discharged from the chamber 50 by the third processing unit exhaust system 67. Here, the time for which the oxygen gas is supplied into the chamber 50 is preferably approximately 10 seconds, and the temperature of the stage heater 51 is preferably set to be in a range of 100 to 200° C. Moreover, the flow rate of the oxygen gas supplied in from the oxygen gas supply line 197 is preferably in a range of 1 to 5 SLM.

Moreover, in step S104, the wave retarding member 223 and the slot electrode 219 are held at a desired temperature, and hence deformation such as thermal expansion does not occur. As a result, the slits 224 in the slit pairs 225 can be maintained at their optimum length, whereby the microwaves can be introduced into the chamber 50 uniformly (without being concentrated in places) and at a desired density (with no decrease in density).

Next, the wafer W on which the innermost SiOBr layer has been exposed through the removal of the CF-type deposit layer of the deposit film on the side surfaces of the trenches is housed in the chamber 38 of the second processing unit 34, and is subjected to the same processing as in step S101 described above (step S105), and then the wafer W is mounted on the stage heater 51 in the chamber 50 of the third processing unit 36, and is subjected to the same processing as in step S102 described above (step S106). As a result, the innermost SiOBr layer is removed, whereupon the present process comes to an end.

Note that steps S103 and S104 described above correspond to the organic layer removal processing.

According to the substrate processing apparatus of the present embodiment described above, the third processing unit 36 has the oxygen gas supply system 192 and the oxygen gas supply ring 198 that supply oxygen gas into the chamber 50, and the antenna apparatus 191 that introduces microwaves into the chamber 50. For a wafer W having formed on side surfaces of trenches therein a CF-type deposit layer covered with an outermost SiOBr layer, upon product produced from the SiOBr layer through chemical reaction with ammonia gas and hydrogen fluoride gas being heated, the product is vaporized so as to expose the CF-type deposit layer. Moreover, upon microwaves being introduced into the chamber 50 into which oxygen gas has been supplied, the oxygen gas is excited so that oxygen radicals are produced. The exposed CF-type deposit layer (organic layer) is exposed to the produced oxygen radicals, whereupon the oxygen radicals decompose the CF-type deposit layer into gas molecules such as CO, CO₂, and F₂ through chemical reaction. The CF-type deposit layer can thus be removed continuously following on from the outermost SiOBr layer, and hence the SiOBr layer and the CF-type deposit layer can be removed efficiently.

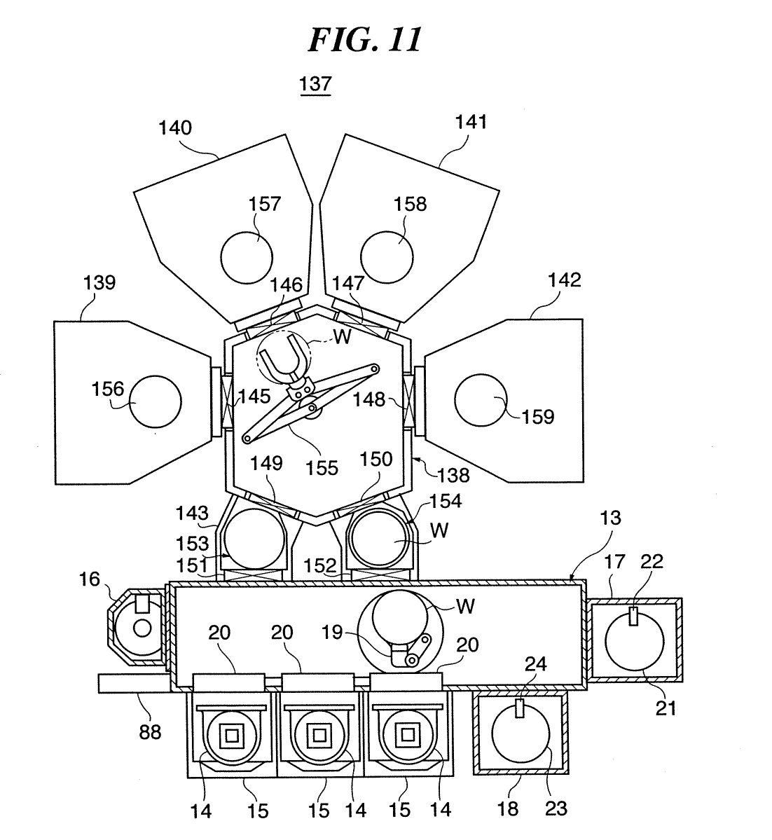

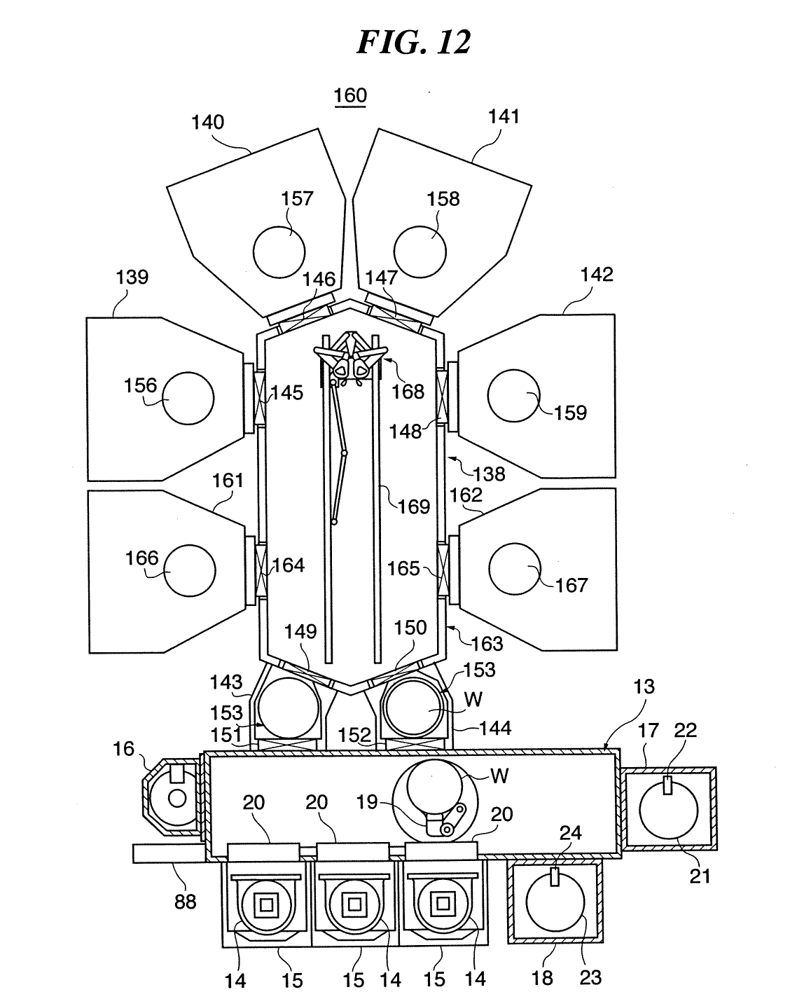

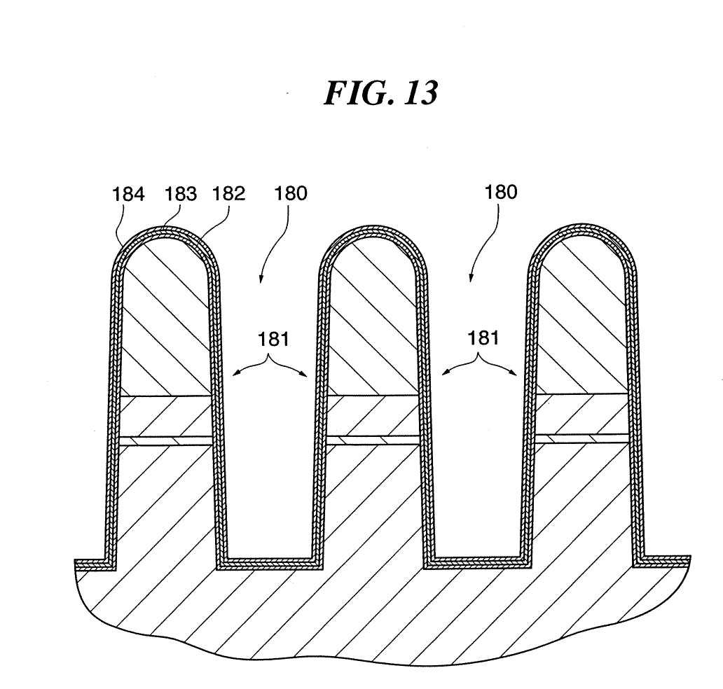

The substrate processing apparatus according to the present embodiment described above is not limited to being a substrate processing apparatus of a parallel type having two process ships arranged in parallel with one another as shown in FIG. 1, but rather as shown in FIGS. 11 and 12, the substrate processing apparatus may instead be one having a plurality of processing units arranged in a radial manner as vacuum processing chambers in which predetermined processing is carried out on the wafers W.

FIG. 11 is a plan view schematically showing the construction of a first variation of the substrate processing apparatus according to the present embodiment described above. In FIG. 11, component elements the same as ones of the substrate processing apparatus 10 shown in FIG. 1 are designated by the same reference numerals as in FIG. 1, and description thereof is omitted here.

As shown in FIG. 11, the substrate processing apparatus 137 is comprised of a transfer unit 138 having a hexagonal shape in plan view, four processing units 139 to 142 arranged in a radial manner around the transfer unit 138, a loader unit 13, and two load lock units 143 and 144 that are each disposed between the transfer unit 138 and the loader unit 13 so as to link the transfer unit 138 and the loader unit 13 together.

The internal pressure of the transfer unit 138 and each of the processing units 139 to 142 is held at vacuum. The transfer unit 138 is connected to the processing units 139 to 142 by vacuum gate valves 145 to 148 respectively.

In the substrate processing apparatus 137, the internal pressure of the transfer unit 138 is held at vacuum, whereas the internal pressure of the loader unit 13 is held at atmospheric pressure. The load lock units 143 and 144 are thus provided respectively with a vacuum gate valve 149 or 150 in a connecting part between that load lock unit and the transfer unit 138, and an atmospheric door valve 151 or 152 in a connecting part between that load lock unit and the loader unit 13, whereby the load lock units 143 and 144 are each constructed as a preliminary vacuum transfer chamber whose internal pressure can be adjusted. Moreover, the load lock units 143 and 144 have respectively therein a wafer mounting stage 153 or 154 for temporarily mounting a wafer W being transferred between the loader unit 13 and the transfer unit 138.

The transfer unit 138 has disposed therein a frog leg-type transfer arm 155 that can bend/elongate and turn. The transfer arm 155 transfers the wafers W between the processing units 139 to 142 and the load lock units 143 and 144.

The processing units 139 to 142 have respectively therein mounting stages 156 to 159 on which a wafer W to be processed is mounted. Here, the processing units 139 and 140 are each constructed like the first processing unit 25 in the substrate processing apparatus 10, the processing unit 141 is constructed like the second processing unit 34 in the substrate processing apparatus 10, and the processing unit 142 is constructed like the third processing unit 36 in the substrate processing apparatus 10. Each of the wafers W can thus be subjected to etching in the processing unit 139 or 140, the COR in the processing unit 141, and the PHT and the organic layer removal processing in the processing unit 142.

In the substrate processing apparatus 137, the substrate processing method according to the present embodiment described above is implemented by transferring a wafer W having a deposit film comprised of an SiOBr layer, a CF-type deposit layer, and an SiOBr layer formed on side surfaces of trenches into the processing unit 141 and carrying out the COR, and then transferring the wafer W into the processing unit 142 and carrying out the PHT and the organic layer removal processing.

Operation of the component elements in the substrate processing apparatus 137 is controlled using a system controller constructed like the system controller in the substrate processing apparatus 10.

FIG. 12 is a plan view schematically showing the construction of a second variation of the substrate processing apparatus according to the present embodiment described above. In FIG. 12, component elements the same as ones of the substrate processing apparatus 10 shown in FIG. 1 or the substrate processing apparatus 137 shown in FIG. 11 are designated by the same reference numerals as in FIG. 1 or FIG. 11, and description thereof is omitted here.

As shown in FIG. 12, compared with the substrate processing apparatus 137 shown in FIG. 11, the substrate processing apparatus 160 has an additional two processing units 161 and 162, and the shape of a transfer unit 163 of the substrate processing apparatus 160 is accordingly different from the shape of the transfer unit 138 of the substrate processing apparatus 137. The additional two processing units 161 and 162 are respectively connected to the transfer unit 163 via a vacuum gate valve 164 or 165, and respectively have therein a wafer W mounting stage 166 or 167. The processing unit 161 is constructed like the first processing unit 25 in the substrate processing apparatus 10, and the processing unit 162 is constructed like the second processing unit 34 in the substrate processing apparatus 10.

Moreover, the transfer unit 163 has therein a transfer arm unit 168 comprised of two SCARA-type transfer arms. The transfer arm unit 168 moves along guide rails 169 provided in the transfer unit 163, and transfers the wafers W between the processing units 139 to 142, 161 and 162, and the load lock units 143 and 144.

In the substrate processing apparatus 160, as in the substrate processing apparatus 137, the substrate processing method according to the present embodiment described above is implemented by transferring a wafer W having a deposit film comprised of an SiOBr layer, a CF-type deposit layer, and an SiOBr layer formed on side surfaces of trenches into the processing unit 141 or the processing unit 162 and carrying out the COR, and then transferring the wafer W into the processing unit 142 and carrying out the PHT and the organic layer removal processing.

Operation of the component elements in the substrate processing apparatus 160 is again controlled using a system controller constructed like the system controller in the substrate processing apparatus 10.

It is to be understood that the object of the present invention can also be attained by supplying to the EC 89 a storage medium in which a program code of software that realizes the functions of the embodiment described above is stored, and then causing a computer (or CPU, MPU, or the like) of the EC 89 to read out and execute the program code stored in the storage medium.

In this case, the program code itself read out from the storage medium realizes the functions of the embodiment described above, and hence the program code and the storage medium in which the program code is stored constitute the present invention.

The storage medium for supplying the program code may be, for example, a floppy (registered trademark) disk, a hard disk, a magnetic-optical disk, an optical disk such as a CD-ROM, a CD-R, a CD-RW, a DVD-ROM, a DVD-RAM, a DVD-RW, or a DVD+RW, a magnetic tape, a non-volatile memory card, or a ROM. Alternatively, the program code may be downloaded via a network.

Moreover, it is to be understood that the functions of the embodiment described above may be accomplished not only by executing a program code read out by a computer, but also by causing an OS (operating system) or the like that operates on the computer to perform a part or all of the actual operations based on instructions of the program code.

Furthermore, it is to be understood that the functions of the embodiment described above may also be accomplished by writing a program code read out from the storage medium into a memory provided on an expansion board inserted into a computer or in an expansion unit connected to the computer, and then causing a CPU or the like provided on the expansion board or in the expansion unit to perform a part or all of the actual operations based on instructions of the program code.

The form of the program code may be, for example, object code, program code executed by an interpreter, or script data supplied to an OS.

What is claimed is:

1. A substrate processing apparatus that carries out processing on a substrate having formed on a surface thereof an organic layer covered with an oxide layer, the substrate processing apparatus comprising:
a chemical reaction processing apparatus that subjects the oxide layer to chemical reaction with gas molecules so as to produce a product on the surface of the substrate; and
a heat treatment apparatus that heats the substrate on the surface of which the product has been produced;
wherein said heat treatment apparatus comprises a housing chamber in which the substrate is housed, an oxygen gas supply system that supplies oxygen gas into said housing chamber, and a microwave introducing apparatus that introduces microwaves into said housing chamber.

2. A substrate processing apparatus as claimed in claim 1, wherein said microwave introducing apparatus has a disk-shaped antenna disposed such as to face the substrate housed in said housing chamber, and an electromagnetic wave absorber disposed such as to surround a peripheral portion of said antenna.

3. A substrate processing apparatus as claimed in claim 1, wherein the organic layer is a layer made of CF-type deposit.

4. A substrate processing method for carrying out processing on a substrate having formed on a surface thereof an organic layer covered with an oxide layer, the substrate processing method comprising:
a chemical reaction processing step of subjecting the oxide layer to chemical reaction with gas molecules so as to produce a product on the surface of the substrate;
a heat treatment step of heating the substrate on the surface of which the product has been produced;
an oxygen gas supply step of supplying oxygen gas toward an upper portion of the substrate on which the heat treatment has been carried out; and
a microwave introducing step of introducing microwaves toward the upper portion of the substrate onto which the oxygen gas has been supplied.

5. A computer-readable storage medium storing a program for causing a computer to implement a substrate processing method for carrying out processing on a substrate having formed on a surface thereof an organic layer covered with an oxide layer, the program comprising:
a chemical reaction processing module for subjecting the oxide layer to chemical reaction with gas molecules so as to produce a product on the surface of the substrate;
a heat treatment module for heating the substrate on the surface of which the product has been produced;
an oxygen gas supply module for supplying oxygen gas toward an upper portion of the substrate on which the heat treatment has been carried out; and
a microwave introducing module for introducing microwaves toward the upper portion of the substrate onto which the oxygen gas has been supplied.
